(19) United States
(12) Patent Application Publication
(10) Pub. No.: US 2010/0197111 A1
(43) Pub. Date: Aug. 5, 2010

(54) METHOD OF MANUFACTURING MEMORY DEVICE AND METHOD OF MANUFACTURING PHASE-CHANGE MEMORY DEVICE USING THE SAME

(75) Inventors: Hye Jin SEO, Gyeonggi-do (KR); Keum Bum LEE, Gyeonggi-do (KR); Hyung Suk LEE, Gyeonggi-do (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Kyoungki-do (KR)

(21) Appl. No.: 12/623,508

(22) Filed: Nov. 23, 2009

(30) Foreign Application Priority Data
Jan. 30, 2009 (KR) 10-2009-0007604

(51) Int. Cl. H01L 21/77; H01L 21/22; H01L 21/20

(52) U.S. Cl. 438/430; 438/530; 438/478; 257/E21.09; 257/E21.04; 257/E21.135; 257/E21.598

(57) ABSTRACT

A method of manufacturing a memory device and a phase-change memory device is presented. The method of manufacturing the memory device includes performing Ge ion implantation on a top surface of a first layer. The method also includes performing a fast heat treatment on the ion-implanted first layer. The method also includes forming a second layer on a top of the fast heat-treated first layer.

### CROSS-REFERENCES TO RELATED PATENT APPLICATION

The present application claims priority under 35 U.S.C 119(a) to Korean Application No. 10-2009-0007604, filed on Jan. 30, 2009, in the Korean Intellectual Property Office, which is incorporated herein by reference in its entirety as set forth in full.

### BACKGROUND OF THE INVENTION

1. Field of the Invention

The present invention relates to a method of manufacturing a memory devices, and, more particularly, to a method of manufacturing a memory device and a method of manufacturing a phase-change memory device using the method, in which different types of layers are stacked.

2. Description of the Related Art

Recent research has focused on developing phase-change memory devices (Phase-Change Random Access Memory: PCRAM). PCRAM are characterized in that they have simple phase change memory structures. It is hoped that PCRAMs can be developed to have high integration because they are generally being free of interference problems between adjacent cells. It is also hoped that PCRAMs can be developed to PCRAMs to be able to have high read speeds of as fast as several tens of nanoseconds. It is also hoped that PCRAMs can be developed have relatively high write speeds of as fast as several tens to hundreds of nanoseconds. It is hoped that the cost of producing PCRAMs can be reduced thanks to its excellent compatibility with existing Complementary Metal-Oxide-Semiconductor (CMOS) logic processes. Accordingly, a phase-change memory device has been evaluated as a memory device having a very high potentiality from the standpoint of commercialization.

A phase-change memory device is a memory device configured on the base of the principle that a phase change occurs between the amorphous disordered crystalline structure and that of an ordered crystalline structure of a phase-change film. Phase-change memory devices are often made of a chalcogen bearing compound. As a result of Joule heating that occurs due to a current between upper and lower electrodes the crystalline structure can be reversibly transformed between the amorphous and ordered crystalline states that thus data can be written or erased. The resultant data can be read by exploiting the differences between electric resistances amorphous and ordered crystalline states.

In a conventional phase-change memory device, heaters are formed below a phase-change film that rapidly release heat when a phase change is made. The heaters are electrode patterns having the characteristics of resistors. The heaters function to rapidly heat the phase-change memory device so as to simultaneously cause a reverse reaction and a forward reaction in the phase change of the phase-change film while converting electric energy into thermal energy.

Meanwhile, a nitride film is used as a dielectric film for insulating the heaters from one another. When a process for depositing the phase-change film is performed in the state in which the nitride film has been formed, lifting between the nitride film and the phase-change film occurs.

The reason for this is that such a nitride film has very low adhesion properties due to the physical stresses between interfaces. Nitride films also have thermal expansion coefficients greater than that of an oxide film for insulating vertical PN diodes from one another. Thus nitride film suffer from deterioration due to interfacial adhesion properties while causing stress on a wafer (or a substrate). Furthermore, since the phase-change film is directly deposited on the surface of the nitride film, the adhesive strength of the nitride film itself is deteriorated. As a result, a detaching phenomenon, in which interfaces between the nitride film and the phase-change film are detached from each other, that is, lifting, can occur due to a failure in the adhesion between the interfaces during subsequent processing. Such unwanted lifting may make it impossible to operate the resultant memory devices or may cause failure of the malfunctioning of the devices.

### SUMMARY OF THE INVENTION

Accordingly, the present invention has been made keeping in mind the above problems occurring in the prior art, and an object of the present invention is to provide a method of manufacturing a memory device and a method of manufacturing a phase-change memory device using the method, which can prevent the occurrence of lifting.

In order to accomplish the above object, the present invention provides a method of manufacturing a memory device in which a first layer and a second layer are stacked, comprising performing Ge ion implantation on a top surface of the first layer; performing fast heat treatment on the ion-implanted first layer; and forming the second layer on a top of the fast heat-treated first layer.

Preferably, the first layer comprises a nitride-based film.

Preferably, the Ge ion implantation is performed in a dose of about 1E14 to 1E16 atoms/cm² using an energy of about 10 to 20 keV.

Preferably, the fast heat treatment is performed at a temperature of about 850 to 950° C. for about 20 to 30 seconds.

Preferably, the second layer comprises a phase-change material.

Further, the present invention provides a method of manufacturing a memory device in which a first layer and a second layer are stacked, comprising forming a GeN film on a top surface of the first layer; and forming the second layer on a top of the GeN film.

Preferably, the first layer comprises a nitride-based film.

Preferably, the second layer comprises a phase-change material.

Further, the present invention provides a method of manufacturing a phase-change memory device, comprising forming a first interlayer dielectric film; forming holes by etching the first interlayer dielectric film; forming a heater on an entire surface of each of the holes; filling the holes, in which respective heaters are formed, with a second interlayer dielectric film; performing Ge ion implantation on top surfaces of the heaters and the first interlayer dielectric film as well as of the second interlayer dielectric film; performing fast heat treatment on the ion-implanted heaters and films; and forming a phase-change film, coming into contact with the heaters, on tops of the fast heat-treated heaters and films.

Preferably, the first interlayer dielectric film comprises a nitride-based film.

Preferably, the heater comprises a stacked layer of a Ti film and a TiN film.

Preferably, the second interlayer dielectric film comprises a nitride-based film.

Preferably, the Ge ion implantation is performed in a dose of about 1E14 to 1E16 atoms/cm² using an energy of about 10 to 20 keV.

Preferably, the fast heat processing is performed at a temperature of 850 to 950° C. for about 20 to 30 seconds.

In addition, the present invention provides a method of manufacturing a phase-change memory device, comprising forming a first interlayer dielectric film; forming holes by etching the first interlayer dielectric film; forming a heater on an entire surface of each of the holes; filling the holes, in which respective heaters are formed, with a second interlayer dielectric film; forming a GeN film on tops of the heaters and the first interlayer dielectric film as well as of the second interlayer dielectric film; and forming a phase-change film on a top of the GeN film.

Preferably, the first interlayer dielectric film comprises a nitride-based film.

Preferably, the heater comprises a stacked layer of a Ti film and a TiN film.

Preferably, the second interlayer dielectric film comprises a nitride-based film.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view showing a method of manufacturing a to memory device according to the present invention;

FIG. 2 is a sectional view showing another method of manufacturing a memory device according to the present invention;

FIGS. 3A to 3E are sectional views showing the respective processes of a method of manufacturing a phase-change memory device according to an embodiment of the present invention; and

FIGS. 4A to 4E are sectional views showing the respective processes of a method of manufacturing a phase-change memory device according to another embodiment of the present invention.

### DESCRIPTION OF THE PREFERRED EMBODIMENTS

It is understood herein that the drawings are not necessarily to scale and in some instances proportions may have been exaggerated in order to more clearly depict certain features of the invention

One embodiment of the present invention is configured to perform germanium (hereinafter referred to as ‘Ge’) ion implantation on the top surface of a first layer, and form a second layer on the top of the ion-implanted first layer. Another embodiment of the present invention is configured to form a germanium nitride film (hereinafter referred to as a ‘GeN film’) on the top of the first layer and form the second layer on the top of the GeN film.

Preferably, the first layer is formed as a nitride-based film, and the second layer is formed on the top of the ion-implanted first layer. The memory device is made of a phase-change material in which Ge ion implantation is performed on the top of the first layer. Alternatively, after a GeN film is formed on the top of the first layer, the second layer is formed on the top of the GeN film.

In this way, the stresses between the first layer and the second layer made of different types of materials are mitigated thanks to the Ge ion implantation or the formation of the GeN film. In addition the adhesion between the interface between the first and second layer is found to be excellent and thus improves the adhesion properties when other interfaces made of different types of materials are deposited of the resultant first and second layers.

Therefore, the present invention can improve the driving abilities of devices by preventing lifting between different types of materials.

Hereinafter, embodiments of the present invention will be described in detail with reference to the attached drawings.

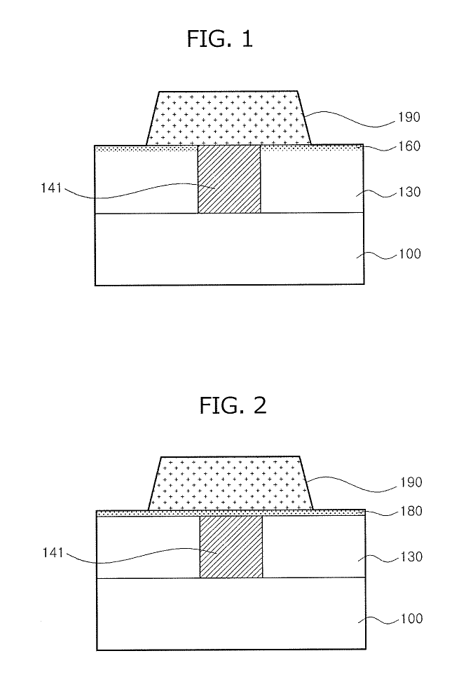

FIG. 1 is a sectional view showing a method of manufacturing a memory device according to the present invention.

Referring to FIG. 1, a first layer 130 which is a nitride-based film is formed on the top of a semiconductor substrate (or wafer) 100. After Ge ion implantation is performed on the top portion 160 of the first layer 130 at a dopant density dose of about 1E14 to 1E16 atoms/cm² using an energy of between about 10 to 20 keV, then fast heat treatment is performed on the ion-implanted first layer at a temperature of about 850 to 950° C. for about 20 to 30 seconds. A second layer 190 made of a phase-change material is subsequently formed on the top of the first layer 130 on which ion implantation and fast heat treatment have been performed.

Reference numeral 141, which has not been described In FIG. 1, denotes a conductive pattern for heaters.

FIG. 2 is a sectional view showing another method of manufacturing a memory device according to the present invention.

Referring to FIG. 2, a first layer 130 which is a nitride-based film is formed on the top of a semiconductor substrate 100. After a GeN film 180 is formed on the top of the first layer 130, a second layer 190 made of a phase-change material is formed on the top of the GeN film 180.

Reference numeral 141, which has not been described in FIG. 2, denotes a conductive pattern for heaters.

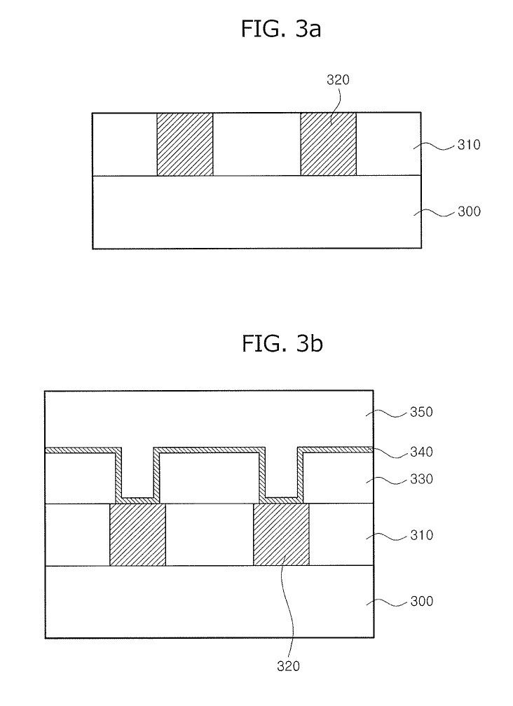

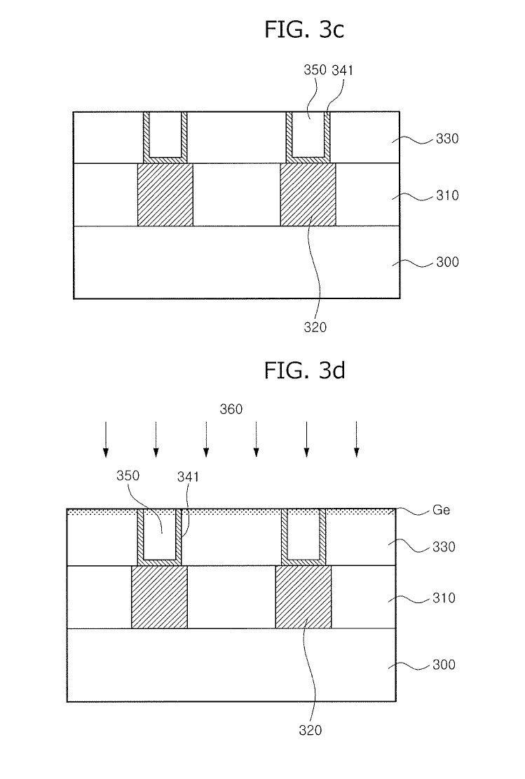

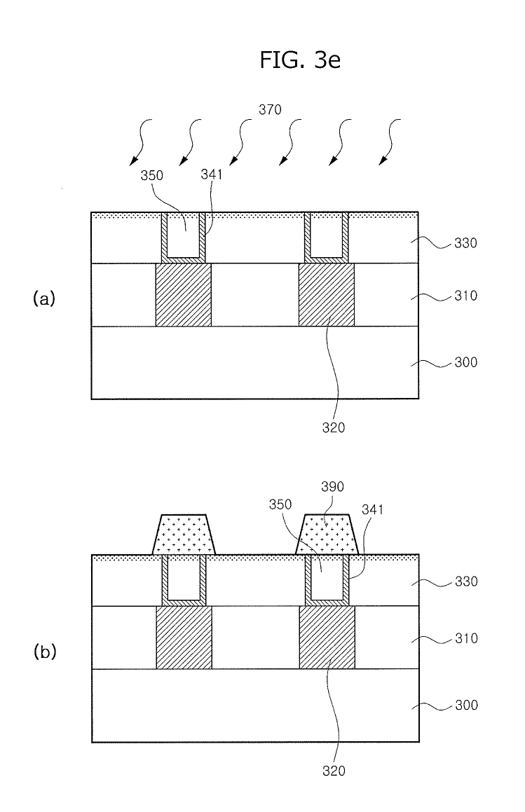

A method of manufacturing a phase-change memory device according to an embodiment of the present invention will be described below with reference to FIGS. 3a to 3e.

Referring to FIG. 3a, an oxide film 310 is deposited on the top of a semiconductor substrate 300 doped with N-type impurities. Thereafter, Chemical Mechanical Polishing (CMP) is performed to planarize the oxide film 310. Next, a mask pattern (not shown) for exposing regions in which switching devices are to be formed is formed on the top of the oxide film 310. Thereafter, the exposed regions of the oxide film 310 are etched by using the mask pattern as an etching mask, and thus a plurality of holes are formed. Next, the mask pattern is removed.

A Selective Epitaxial Growth (SEG) process is performed on the semiconductor substrate 300 in which the holes are formed, and then silicon films are formed in the holes. The silicon films are N-type silicon films. P-type impurity ions are implanted into the silicon films, and thus a plurality of vertical PN diodes 320, that is, switching devices, are formed in the holes. Although not shown in the drawing, a silicide process is performed on the oxide film 310 including the vertical PN diodes 320, and then a silicide film may be formed on the surfaces of the vertical PN diodes 320. The silicide film functions to reduce contact resistance.

Referring to FIG. 3b, after a first interlayer dielectric film 330 is formed on the oxide film 310 including the vertical PN diodes 320, contact holes for exposing the vertical PN diodes 320 are formed by etching the first interlayer dielectric film 330. The first interlayer dielectric film 330 is formed as a nitride-based film. Preferably, the first interlayer dielectric film 330 is made of Si₃N₄. Next, a thin film 340 for use as heaters is then formed on the first interlayer dielectric film 330 in which the thin film 340 is preferably formed over the entire surface of each of the holes. The thin film 340 for heaters is formed as a stacked layer of a Ti film and a TiN film. Next, in order to fill the holes, a second interlayer dielectric film 350 is formed on the top of the thin film 340 for heaters. The second interlayer dielectric film 350 is formed as a nitride-based film. Preferably, the second interlayer dielectric film 350 is preferably made of Si₃N₄.

Referring to FIG. 3c, a CMP process is performed on the top of the second interlayer dielectric film 350 and the thin film 340 for heaters, until the top of the first interlayer dielectric film 330 is exposed. Thus heaters 341 are formed such that a heater is formed on the entire surface of each of the holes. Each of the heaters 341 are preferably formed in the shape of a ring. In this embodiment of the present invention, the heater is formed in the shape of a ring, but the present invention is not limited to this embodiment, and the heater may be formed in the shape of a pillar, a plane, or a dash.

Referring to FIG. 3d, Ge ion implantation 360 is performed on the top surfaces of the heaters 341 and the first interlayer dielectric film 330, as well as of the second interlayer dielectric film 350. The Ge ion implantation 360 is performed to preferably provide a dose of 1E14 to 1E16 atoms/cm² by using an energy of 10 to 20 keV. When Ge ions are implanted, as many Ge ions as possible are implanted into portions of the first interlayer dielectric film and the second interlayer dielectric film.

Referring to FIG. 3e (a), fast heat treatment 370 is performed on the Ge ion-implanted films and heaters for the purpose to rapidly anneal the resultant surface implant damage by curing of the films and heaters. The fast heat treatment 370 is preferably performed at a temperature of about 850 to 950° C. for about 20 to 30 seconds.

In the first interlayer dielectric film 330 and the second interlayer dielectric film 350, stresses on the dielectric films are mitigated thanks to the Ge ion-implantation 360 and the fast heat treatment 370. Thus the adhesive strengths between the first and interlayer dielectric films 330 and 350 is enhanced when a phase-change film is deposited during subsequent processing.

Referring to FIG. 3e (b), a phase-change film 390 coming into contact with the heaters 341 is formed on the top of the films and heaters on which the Ge ion-implantation 360 and the fast heat treatment 370 have been performed. The phase-change film 390 is may be made of any known phase-change composition such as those containing anyone or more of the elements of Te, Se and Ge or combinations thereof. Preferably, the phase-change film 390 may be formed to include at least one of Te, Se, Ge, Sb, Bi, Pb, Sn, As, S, Si, P and O, or may be made of a material selected from a group composed of alloys thereof.

Since the stresses on the interlayer dielectric films 330 and 350 which are nitride-based films are mitigated thanks to the Ge ion implantation 360, then the adhesion properties to the phase-change film 390 are improved, and thus the lifting of the phase-change film can be prevented or at least minimized. In other words, when a phase-change film is directly formed on the tops of nitride films as in the case of the prior art, the adhesion properties between the phase-change film and the nitride films deteriorate due to the stresses on the nitride films, and as a result the phase-change film is more likely to lift off during subsequent processing. However, in the present invention, Ge ion implantation is performed on the surfaces of nitride films, and a phase-change film is formed on the top of the Ge ion-implanted nitride films and thus solves or at least reduces the occurrence of these and other problems. Again it is thought that this problem is attributable to the deterioration of the adhesion properties between the nitride films and the phase-change film which are made of different types of materials.

Thereafter, although not shown in the drawings, a series of well-known subsequent processes are sequentially performed, and thus the manufacture of the phase-change memory device according to the embodiment of the present invention is completed.

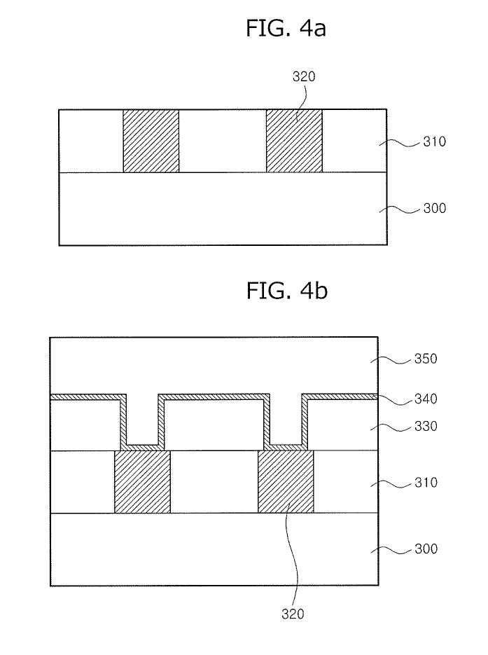

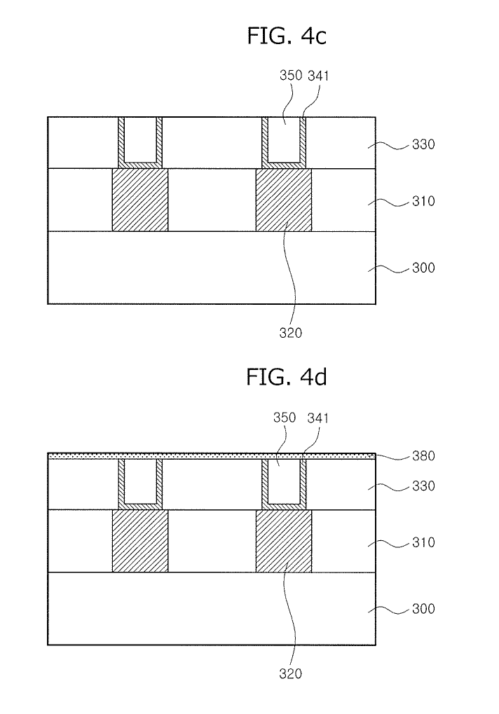

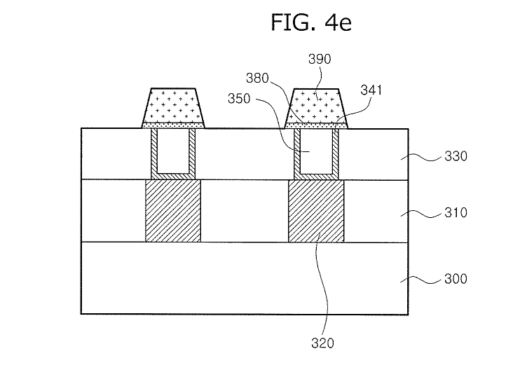

A method of manufacturing a phase-change memory device according to another embodiment of the present invention will be described below with reference to FIGS. 4a to 4e.

Referring to FIG. 4a, after an oxide film is formed on a semiconductor substrate 300 doped with N-type impurities, a plurality of holes are formed by etching the oxide film 310. An SEG process and an ion implantation process are performed on the oxide film 310 in which the holes are formed, and thus a plurality of vertical PN diodes 320, that is, switching devices, are formed in the holes. A silicide film may be formed on the surfaces of the vertical PN diodes 320.

Referring to FIG. 4b, a first interlayer dielectric film 330 is formed on the top of the oxide film 310 including the vertical PN diodes 320, and then contact holes for exposing the vertical PN diodes 320 are formed by etching the first interlayer dielectric film 330. The first interlayer dielectric film 330 may be formed as a nitride-based film. Preferably, the first interlayer dielectric film 330 may be made of Si₃N₄. Thereafter, a thin film 340 for heaters is formed on the top of the first interlayer dielectric film 330 which includes the thin film 340 being formed in the entire surface of each of the holes. The thin film 340 for heaters may be formed as a stacked layer of a Ti film and a TiN film. Next, a second interlayer dielectric film 350 is formed on the top of the thin film 340 for heaters to fill the holes. The second interlayer dielectric film 350 is formed as a nitride-based film. Preferably, the second interlayer dielectric film 350 is made of Si₃N₄.

Referring to FIG. 4c, CMP is performed on the second interlayer dielectric film 350 and the thin film 340 for heaters 40 until the top of the first interlayer dielectric film 330 is exposed. Thus heaters 341 are formed such that a heater is formed on the entire surface of each of the holes.

Referring to FIG. 4d, a GeN film 380 is formed on the tops of the heaters 341 and the first interlayer dielectric film 330 as well as of the second interlayer dielectric film 350. When the GeN film 380 is formed on the tops of the interlayer dielectric films 330 and 350 which are preferably made of Si₃N₄ films, then a stacked layer of the same types of materials is formed, and thus stresses between the interlayer dielectric films 330 and 350 are minimized.

Referring to FIG. 4e, a phase-change film 390 coming into contact with the heaters 341 is formed on the top of the GeN film 380. The phase-change film 390 is may be made of any known phase change material such as those containing anyone or more of the elements of Te, Se and Ge or combinations thereof. Preferably, the phase-change film 390 is formed to include at least one of Te, Se, Ge, Sb, Bi, Pb, Sn, As, S, Si, P and O, and is made of a material selected from a group composed of alloys thereof.

As described above, in the present invention, as the stresses on the interlayer dielectric films 330 and 350 which are nitride-based films are mitigated thanks to the GeN film 380. As a result the adhesion properties between the interlayer dielectric films 330 and 350 and the phase-change film 390 can be improved, and thus the lifting of the phase-change film can be prevented or at least protected against.

Thereafter, although not shown in detail, a series of well-known subsequent processes are sequentially performed, and then the manufacture of the phase-change memory device according to another embodiment of the present invention is completed.

The present invention is configured to perform a Ge ion implantation process and a GeN film deposition process on the tops of nitride films having their own stresses, so that adhesion properties between the nitride films and a phase-change film can be improved, and thus the lifting of the phase-change film can be prevented.

Therefore, the present invention is advantageous in that open failures attributable to lifting occurring when devices are driven can be eliminated.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a memory device in which a first layer and a second layer are stacked, the method comprising:
performing Ge ion implantation on a top surface of the first layer;
performing fast heat treatment on the ion-implanted first layer; and
forming the second layer on a top of the fast heat-treated first layer.

2. The method according to claim 1, wherein the first layer comprises a nitride-based film.

3. The method according to claim 1, wherein the Ge ion implantation is performed to provide a dose between about 1E14 to 1E16 atoms/cm² using an energy of between about 10 to 20 keV.

4. The method according to claim 1, wherein the fast heat treatment is performed at a temperature of between about 850 to 950° C. for about 20 to 30 seconds.

5. The method according to claim 1, wherein the second layer comprises a phase-change material.

6. A method of manufacturing a memory device in which a first layer and a second layer are stacked, comprising:
forming a GeN film on a top surface of the first layer; and
forming the second layer on a top of the GeN film.

7. The method according to claim 6, wherein the first layer comprises a nitride-based film.

8. The method according to claim 6, wherein the second layer comprises a phase-change material.

9. A method of manufacturing a phase-change memory device, comprising:
forming a first interlayer dielectric film;
forming holes by etching the first interlayer dielectric film;
forming a heater on an entire surface of each of the holes;
filling the holes, in which respective heaters are formed, with a second interlayer dielectric film;
performing Ge ion implantation on top surfaces of the heaters, and on the first and second interlayer dielectric films;
performing fast heat treatment to anneal the top surfaces of the heaters and the films; and
forming a phase-change film in contact with the heaters on top of the heaters and the films.

10. The method according to claim 9, wherein the first interlayer dielectric film comprises a nitride-based film.

11. The method according to claim 9, wherein the heater comprises a stacked layer of a Ti film and a TiN film.

12. The method according to claim 9, wherein the second interlayer dielectric film comprises a nitride-based film.

13. The method according to claim 9, wherein the Ge ion implantation is performed in a dose of between about 1E14 to 1E16 atoms/cm² using an energy of between about 10 to 20 keV.

14. The method according to claim 9, wherein the fast heat processing is performed at a temperature of between about 850 to 950° C. for about 20 to 30 seconds.

15. A method of manufacturing a phase-change memory device, comprising:
forming a first interlayer dielectric film;
forming holes by etching the first interlayer dielectric film;
forming a heater on an entire surface of each of the holes;
filling the holes, in which respective heaters are formed, with a second interlayer dielectric film;
forming a GeN film on top of the heaters and the first and second interlayer dielectric films; and
forming a phase-change film on a top of the GeN film.

16. The method according to claim 15, wherein the first interlayer dielectric film comprises a nitride-based film.

17. The method according to claim 15, wherein the heater comprises a stacked layer of a Ti film and a TiN film.

18. The method according to claim 15, wherein the second interlayer dielectric film comprises a nitride-based film.
